(19) United States
(12) Patent Application Publication
(10) Pub. No.: US 2026/0047237 A1
(43) Pub. Date: Feb. 12, 2026

(54) NITRIDE SEMICONDUCTOR DEVICE AND METHOD FOR MANUFACTURING NITRIDE SEMICONDUCTOR DEVICE

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 19/366,680

(22) Filed: Oct. 23, 2025

Related U.S. Application Data
(63) Continuation of application No. PCT/JP2024/015251, filed on Apr. 17, 2024.

(30) Foreign Application Priority Data
May 9, 2023 (JP) 2023-077220

(51) Int. Cl. H10H 20/815; H10H 20/01; H10H 20/819; H10H 20/825

(52) U.S. Cl. CPC H10H 20/815; H10H 20/01335; H10H 20/819; H10H 20/825

(57) ABSTRACT

A nitride semiconductor device includes an amorphous glass substrate having a first surface and a second surface opposite the first surface, a buffer layer provided on the first surface of the amorphous glass substrate, and a nitride semiconductor laminate including at least one gallium nitride layer disposed on the buffer layer. The first surface of the amorphous glass substrate has an uneven structure comprising a convex surface having a flat top portion and a concave surface having a flat bottom portion. The buffer layer and the nitride semiconductor laminate are disposed on the uneven structure.

### CROSS-REFERENCE TO RELATED APPLICATIONS

This application is a Continuation of International Patent Application No. PCT/JP2024/015251, filed on Apr. 17, 2024, which claims the benefit of priority to Japanese Patent Application No. 2023-077220, filed on May 9, 2023, the entire contents of which are incorporated herein by reference.

### FIELD

An embodiment of the present invention relates to a nitride semiconductor device having a nitride semiconductor layer formed on an amorphous glass substrate, and a method for manufacturing the same.

### BACKGROUND

Gallium nitride-based semiconductor films forming light-emitting diodes are deposited on sapphire substrates at temperatures between 800° C. and 1100° C. using methods such as the Metal Organic Chemical Vapor Deposition (MOCVD) method or the Hydride Vapor Phase Epitaxy (HVPE) method. Since sapphire substrates are expensive, development is underway to deposit gallium nitride-based semiconductor films on glass substrates, as used in display manufacturing. For example, a technology has been disclosed where a silicon oxide film is formed on a glass substrate, followed by an amorphous silicon film and an AlₓGa₁₋ₓN buffer layer on this silicon oxide film, and then a crystalline nitride compound semiconductor is deposited on top at temperatures around 700° C. to 850° C. (refer to, for example, Japanese laid-open patent publication No. 2000-124140).

Generally, glass substrates have a low glass transition temperature, therefore, when depositing gallium nitride-based semiconductor films, it is necessary to reduce the deposition temperature while maintaining crystallinity. Compared to sapphire substrates, the amorphous glass substrate readily absorbs moisture. When heated during deposition, the absorbed moisture can desorb and be incorporated as impurities into the gallium nitride-based semiconductor film, potentially reducing its crystallinity. Furthermore, while glass substrates exhibit isotropic thermal expansion due to their amorphous structure, gallium nitride and other gallium nitride-based semiconductor films possess anisotropic thermal expansion, consequently, thermal stress may act in unintended directions on gallium nitride-based semiconductor films deposited on amorphous glass substrates.

### SUMMARY

A nitride semiconductor device in an embodiment according to the present invention includes an amorphous glass substrate having a first surface and a second surface opposite the first surface, a buffer layer provided on the first surface of the amorphous glass substrate, and a nitride semiconductor laminate including at least one gallium nitride layer disposed on the buffer layer. The first surface of the amorphous glass substrate has an uneven structure comprising a convex surface having a flat top portion and a concave surface having a flat bottom portion. The buffer layer and the nitride semiconductor laminate are disposed on the uneven structure.

A method for manufacturing a nitride semiconductor device in an embodiment according to the present invention, the method includes forming an uneven structure on a first surface of an amorphous glass substrate having the first surface and a second surface opposite the first surface, the uneven structure including a convex surface having a flat top portion and a concave surface having a flat bottom portion, forming a buffer layer on the uneven structure, and forming a nitride semiconductor laminate including at least one gallium nitride layer on the buffer layer. The uneven structure is formed by etching the amorphous glass substrate.

### BRIEF DESCRIPTION OF DRAWINGS

FIG. 1 is a cross-sectional structure of a nitride semiconductor device 100 according to an embodiment of the present invention.

FIG. 2A is a plan view showing the configuration of an amorphous glass substrate used in a nitride semiconductor device 100 according to an embodiment of the present invention.

FIG. 2B is a cross-sectional view of the amorphous glass substrate corresponding to the region between A1 and A2 shown in FIG. 2A.

FIG. 2C is a plan view showing the configuration of an amorphous glass substrate used in a nitride semiconductor device 100 according to an embodiment of the present invention.

FIG. 2D is a plan view showing the configuration of an amorphous glass substrate used in a nitride semiconductor device 100 according to an embodiment of the present invention.

FIG. 2E is a plan view showing the configuration of an amorphous glass substrate used in a nitride semiconductor device 100 according to an embodiment of the present invention.

FIG. 2F is a plan view showing the configuration of an amorphous glass substrate used in a nitride semiconductor device 100 according to an embodiment of the present invention.

FIG. 3A is a flow chart illustrating a method for manufacturing a nitride semiconductor device according to an embodiment of the present invention.

FIG. 3B is a flow chart illustrating a method for manufacturing a nitride semiconductor device according to an embodiment of the present invention.

FIG. 3C is a flow chart illustrating a method for manufacturing a nitride semiconductor device according to an embodiment of the present invention.

FIG. 4A is a cross-sectional view illustrating a method for manufacturing a nitride semiconductor device according to an embodiment of the present invention.

FIG. 4B is a cross-sectional view illustrating a method for manufacturing a nitride semiconductor device according to an embodiment of the present invention.

FIG. 4C is a cross-sectional view illustrating a method for manufacturing a nitride semiconductor device according to an embodiment of the present invention.

FIG. 4D is a cross-sectional view illustrating a method for manufacturing a nitride semiconductor device according to an embodiment of the present invention.

FIG. 4E is a cross-sectional view illustrating a method for manufacturing a nitride semiconductor device according to an embodiment of the present invention.

FIG. 4F is a cross-sectional view illustrating a method for manufacturing a nitride semiconductor device according to an embodiment of the present invention.

FIG. 5 is a cross-sectional structure of a nitride semiconductor device 100 according to an embodiment of the present invention.

FIG. 6 is a cross-sectional structure of a nitride semiconductor device 100 according to an embodiment of the present invention.

### DESCRIPTION OF EMBODIMENTS

Hereinafter, embodiments of the present invention are described with reference to the drawings. However, the present invention can be implemented in many different aspects and should not be construed as being limited to the description of the following embodiments. For the sake of clarifying the explanation, the drawings may be expressed schematically with respect to the width, thickness, shape, and the like of each part compared to the actual aspect, but this is only an example and does not limit the interpretation of the present invention. For this specification and each drawing, elements similar to those described previously with respect to previous drawings may be given the same reference sign (or a number followed by A, B, or a, b, or the like) and a detailed description may be omitted as appropriate. The terms “first” and “second” appended to each element are a convenience sign used to distinguish them and have no further meaning except as otherwise explained.

### First Embodiment

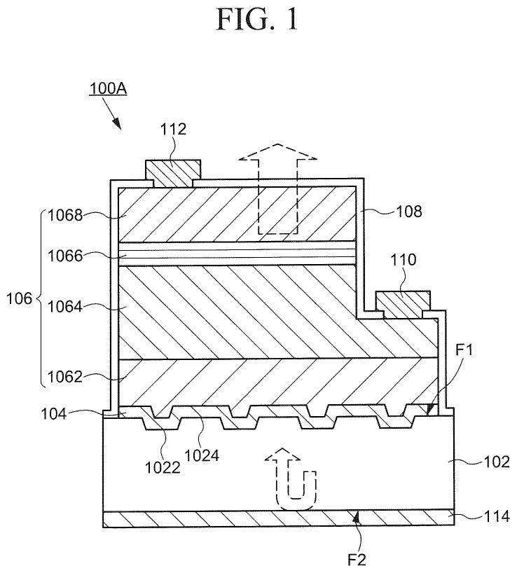

FIG. 1 shows a cross-sectional view of a nitride semiconductor device 100A according to an embodiment of the present invention. The nitride semiconductor device 100A includes a buffer layer 104 on an amorphous glass substrate 102, a nitride semiconductor laminate 106 disposed on the buffer layer 104, a passivation layer 108, as well as an n-electrode 110 and a p-electrode 112. As evident from this structure, the nitride semiconductor device 100A shown in this embodiment is a device functioning as a light-emitting diode (LED).

The amorphous glass substrate 102 has a first surface F1 and a second surface F2, the buffer layer 104, the nitride semiconductor laminate 106, the passivation layer 108, the n-electrode 110, and the p-electrode 112 are provided on the first surface F1. A compensation layer 114 is provided on the second surface F2 of the amorphous glass substrate 102. The compensation layer 114 is disposed in the region overlapping the buffer layer 104 and the nitride semiconductor laminate 106.

FIG. 1 shows a nitride semiconductor laminate 106 composed of an undoped nitride semiconductor layer 1062, an n-type nitride semiconductor layer 1064, a light-emitting layer 1066, and a p-type nitride semiconductor layer 1068 stacked together. At least one layer among the undoped nitride semiconductor layer 1062, the n-type nitride semiconductor layer 1064, and the p-type nitride semiconductor layer 1068 is formed from gallium nitride, and the gallium nitride layer possesses crystallinity. The light-emitting layer 1066 has a structure where multiple types of gallium nitride-based semiconductor layers with different bandgaps are stacked to form quantum wells.

The nitride semiconductor laminate 106 in FIG. 1 is just one example and any stack structure that enables LED operation may be used.

The passivation layer 108 is provided to cover the nitride semiconductor laminate 106, with openings formed in a region contacting the n-type nitride semiconductor layer 1064 and a region contacting the p-type nitride semiconductor layer 1068. Through these openings, the n-electrode 110 forms a contact with the n-type nitride semiconductor layer 1064, and the p-electrode 112 forms a contact with the p-type nitride semiconductor layer 1068.

The amorphous glass substrate 102 has an uneven structure formed on the first surface F1. Specifically, the first surface F1 of the amorphous glass substrate 102 has a concave portion 1022 and a convex portion 1024 formed thereon. The concave portion 1022 is a region recessed relative to the convex portion 1024, while the convex portion 1024 is a region protruding relative to the concave portion 1022. The first surface F1 of the amorphous glass substrate 102 serves as the growth surface for the crystalline nitride semiconductor layer, and the nitride semiconductor laminate 106 is formed on this concave-convex surface. The details of each part of the nitride semiconductor device 100A are described below.

### (1) Amorphous Glass Substrate

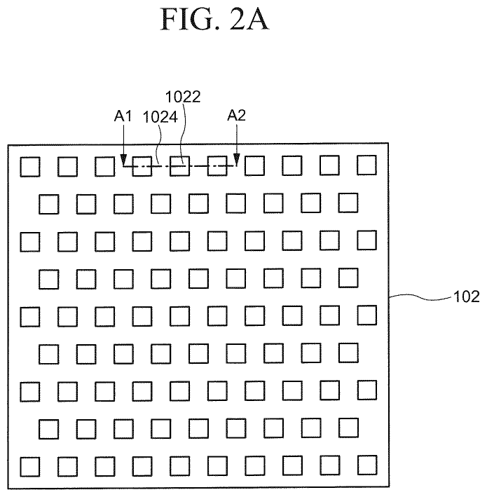

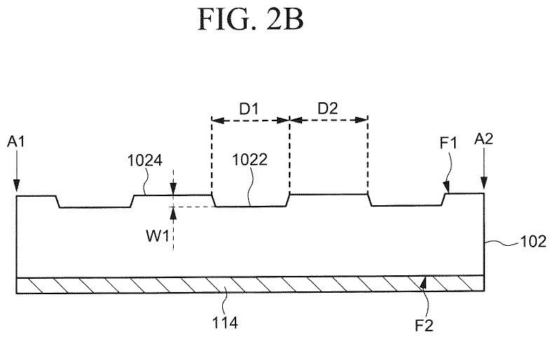

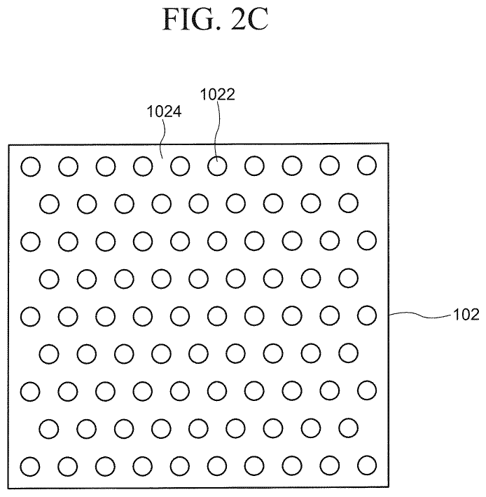

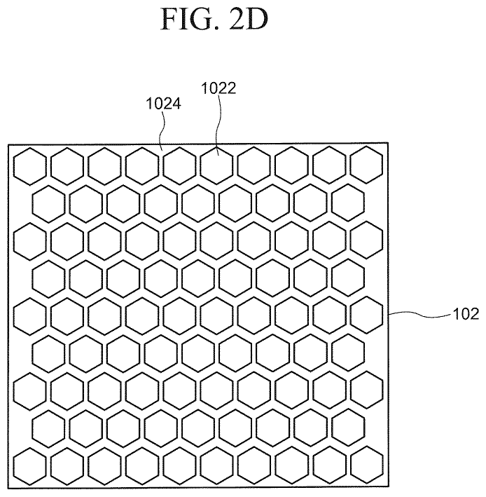

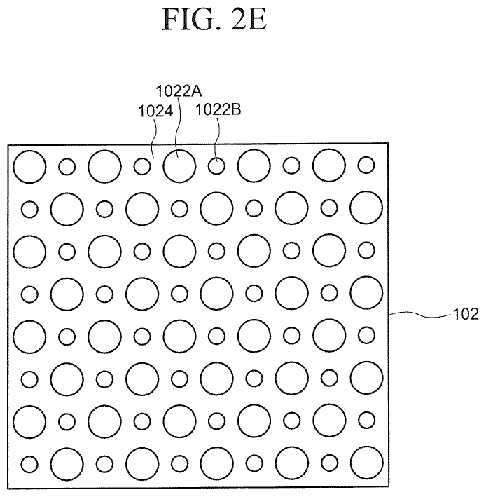

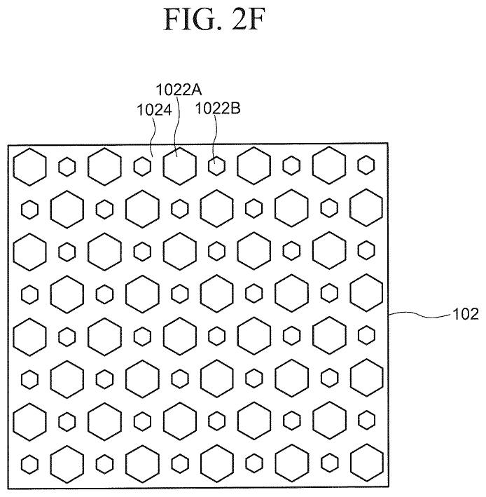

FIG. 2A shows a plan view of the amorphous glass substrate 102, and FIG. 2B shows a cross-sectional view corresponding to a section A1-A2 in the plan view. As described above, the amorphous glass substrate 102 has a first surface F1 and a second surface F2 opposite the first surface F1, and the first surface F1 has an uneven structure.

As shown in the cross-sectional view of FIG. 2B, the concave portion 1022 has a flat bottom surface, and the convex portion 1024 has a flat top surface. A step is formed at the boundary between the concave portion 1022 and the convex portion 1024. This stepped portion may be vertically upright or, as illustrated, may form an inclined surface. Although a buffer layer 104 and a nitride semiconductor laminate 106 are formed on the first surface F1, considering the coverage of the deposited film, it is preferable that the surface of the step portion at the boundary between the concave portion 1022 and the convex portion 1024 has a certain slope and is an inclined surface. To grow a crystalline gallium nitride-based semiconductor on the first surface F1, it is preferable that the concave portion 1022 has a flat bottom surface and the convex portion 1024 has a flat top surface.

A maximum length D1 of the flat surface of the concave portion 1022 is 5 μm to 80 μm. Similarly, a maximum length D2 of the flat surface of the convex portion 1024 (the distance between the concave portion 1022 and an adjacent concave portion) is also 5 μm to 80 μm. When measured from the upper surface of the convex portion 1024, the depth of the concave portion 1022 is 0.3 μm to 3.0 μm. The amorphous glass substrate 102 has a thickness of 0.5 mm to 1.1 mm. The concave portion 1022 can also be regarded as a region where the surface of the amorphous glass substrate 102 has been removed to a thickness of one-hundredth or less.

The concave portions 1022 and convex portions 1024 of this size may be randomly arranged on the first surface F1 of the amorphous glass substrate 102, but it is preferable that they are periodically arranged as shown by the figure. The size of the nitride semiconductor device 100A as viewed in a plan view can be set appropriately. The nitride semiconductor device 100A may, for example, belong to the category of micro-LEDs with a diagonal length of tens of micrometers or mini-LEDs with a diagonal length of around one hundred micrometers, or it may be a conventional LED with a diagonal length of around several millimeters. The size of the uneven structure formed by the concave portion 1022 and the convex portion 1024 can be considered sufficiently small relative to such chip sizes. To reduce variation between devices fabricated by growing homogeneous gallium nitride crystals on the amorphous glass substrate 102, it is preferable that the concave portion 1022 and the convex portion 1024 are arranged periodically.

The amorphous glass substrate 102 preferably contains a low amount of alkali metal components to prevent metal contamination of the nitride semiconductor laminate 106. For example, the alkali metal content of the amorphous glass substrate 102 is preferably 0.1 mass % or less. Specifically, the amorphous glass substrate 102 is preferably an amorphous glass having an amorphous glass composition, for example, an alumino-borosilicate glass or an aluminosilicate glass. The amorphous glass substrate 102 is used in liquid crystal displays and organic electroluminescent (OLED) displays, and large-area glass substrates available on the market, referred to as mother glass, can be applied.

There is no specific limitation on the thickness of the amorphous glass substrate 102. From the perspective of reducing warpage, it is preferable for the thickness of the amorphous glass substrate 102 to be sufficiently greater than the thickness of the nitride semiconductor laminate 106. For example, the amorphous glass substrate 102 is preferably at least 50 times thicker than the thickness of the nitride semiconductor laminate 106. As mentioned above, the amorphous glass substrate 102 is preferably 0.5 mm to 1.0 mm thick.

The amorphous glass substrate 102 is amorphous and generally lacks a crystalline structure, although a crystalline structure may exist in minute regions. The amorphous glass substrate 102 is preferably transparent to visible light.

The amorphous glass substrate 102 preferably possesses heat resistance capable of withstanding the process temperature (maximum processing temperature) of the nitride semiconductor device 100A. For example, when the process temperature (maximum processing temperature) of the nitride semiconductor device 100A is less than 650° C., the heat resistance of the amorphous glass substrate 102 should preferably be at least 650° C. Specifically, the lower limit of the glass transition temperature of the amorphous glass substrate 102 should preferably be 650° C. or higher, and further preferably 720° C. or higher. The upper limit of the glass transition temperature of the amorphous glass substrate 102 is preferably 900° C. or less, and further preferably 810° C. or less. For similar reasons, the lower limit of the softening point of the amorphous glass substrate 102 is preferably 900° C. or higher, and further preferably 950° C. or higher. The upper limit of the softening point of the amorphous glass substrate 102 is preferably 1150° C. or less, and further preferably 1050° C. or less.

The upper limit of the thermal expansion coefficient of the amorphous glass substrate 102 is preferably less than 4.2×10⁻⁶/K (4.2 ppm/K), and further preferably less than 4.0×10⁻⁶/K (4.0 ppm/K). The lower limit of the thermal expansion coefficient of the amorphous glass substrate 102 is preferably greater than 3.0×10⁻⁶/K (3.0 ppm/K) and even greater than 3.5×10⁻⁶/K (3.5 ppm/K). That is, the thermal expansion coefficient of the amorphous glass substrate 102 is preferably generally between 3.5×10⁻⁶ and 3.9×10⁻⁶/K (3.5 to 3.9 ppm/K).

The thermal expansion coefficients of the buffer layer 104 and aluminum oxide and aluminum nitride, which form the compensation layer 114, and of gallium nitride, which constitutes the nitride semiconductor laminate 106, all formed on the amorphous glass substrate 102, are different from that of the amorphous glass substrate 102. Table 1 shows the primary physical property values for each material, specifically the thermal expansion coefficients, densities, lattice constants, and refractive indices of glass, aluminum oxide, aluminum nitride, and gallium nitride. Focusing on the thermal expansion coefficients, the glass (amorphous glass substrate) exhibits no anisotropy in its thermal expansion coefficient due to its amorphous nature. In contrast, aluminum oxide, aluminum nitride, and gallium nitride possess crystalline structures, resulting in different thermal expansion coefficients along the a-axis direction (parallel to the substrate plane) and the c-axis direction (perpendicular to the substrate plane).

TABLE 1

| | | Aluminum | Aluminum | Gallium |
|---|---|---|---|---|
| | Glass | Oxide | Nitride | Nitride |
| Thermal Expansion | 3.5~3.9 | a-axis: 4.5 | a-axis: 4.2 | a-axis: 5.6 |
| Coefficient [ppm/K] | | c-axis: 5.3 | c-axis: 5.3 | c-axis: 3.2 |
| Density [g/cm³] | 2.50~2.59 | 3.98 | 3.30 | 6.15 |
| Lattice Constant [Å] | — | 2.747 as a | 3.112 | 3.189 |
| | | hexagonal | | |
| | | crystal | | |
| Refractive Index | 1.51 | 1.77 | 2.05 | 2.40 |

While the amorphous glass substrate 102 exhibits isotropic thermal expansion, gallium nitride does not. Furthermore, focusing on the thermal expansion coefficient along the a-axis direction reveals a significant disparity between the two materials' coefficients. Therefore, it is anticipated that thermal stress will act on the gallium nitride on the amorphous glass substrate 102 in unintended directions, causing strain to develop in the crystal.

The amorphous glass substrate 102 according to the present embodiment, as described above, has an uneven structure formed on the first surface F1, and includes regions with a thicker plate thickness (regions with a larger volume) and regions with a thinner plate thickness (regions with a smaller volume). As described, it is possible to mitigate the isotropy of thermal expansion by locally varying the thickness (volume) of the amorphous glass substrate 102, thereby reducing the effect of thermal stress on the gallium nitride layer deposited thereon. Furthermore, it is advantageous for three-dimensional crystal growth to arrange an uneven structure on the amorphous glass substrate 102, as the nitride semiconductor formed in the concave portions will experience greater compressive stress compared to the regions adjacent to the convex portions due to substrate heating during film deposition.

Although not shown in the figure, a base layer may be provided on the first surface F1 of the amorphous glass substrate 102 to prevent diffusion of impurities (for example, moisture or sodium (Na), and the like). The base layer is preferably formed from an inorganic insulating material, such as silicon oxide or silicon nitride.

### (2) Compensation Layer

The compensation layer 114 is provided on the second surface F2 of the amorphous glass substrate 102. The compensation layer 114 can reduce warpage of the amorphous glass substrate 102 caused by the difference in thermal expansion coefficients between the amorphous glass substrate 102 and each layer forming the nitride semiconductor laminate 106, due to its thermal expansion coefficient having a predetermined range. The thermal expansion coefficient of the compensation layer 114 is preferably greater than the thermal expansion coefficient of the amorphous glass substrate 102 and less than the thermal expansion coefficients of the layers of the nitride semiconductor laminate 106 (undoped nitride semiconductor layer 1062, n-type nitride semiconductor layer 1064, light-emitting layer 1066, and p-type nitride semiconductor layer 1068).

The lower limit of the thermal expansion coefficient of the compensation layer 114 is preferably greater than, for example, 4.0×10⁻⁶/K (4.0 ppm/K), and preferably greater than 4.1×10⁻⁶/K (4.1 ppm/K). The upper limit of the thermal expansion coefficient of the compensation layer 114 is preferably less than, for example, 5.0×10⁻⁶/K (5.0 ppm/K), and preferably less than 4.6×10⁻⁶/K (4.6 ppm/K). As shown in Table 1, the thermal expansion coefficient of aluminum oxide is 4.5 (a-axis) to 5.3 (c-axis), and the thermal expansion coefficient of aluminum nitride is 4.2 (a-axis) to 5.3 (c-axis), making them suitable for use as the compensation layer 114. However, the upper and lower limits of the thermal expansion coefficient of the compensation layer 114 are not limited to these values.

The thermal conductivity of the compensation layer 114 should preferably exceed, for example, 10 W/m·K, and more preferably 40 W/m·K. It is possible to uniformly conduct heat throughout the amorphous glass substrate 102 during the formation process of the nitride semiconductor laminate 106 and achieve uniform in-plane characteristics by setting the thermal conductivity of the compensation layer 114 within a predetermined range. The thermal conductivity of the compensation layer 114 can be adjusted by the film density. The lower limit of the film density of the compensation layer 114 is preferably 2.50 g/cm³ or more, and further preferably 2.60 g/cm³ or more. The upper limit of the film density of the compensation layer 114 is preferably 4.10 g/cm³ or less, and further preferably 4.00 g/cm³ or less.

As shown in Table 1, when aluminum oxide is used as the compensation layer 114, a film density of 3.98 g/cm³ can be obtained, and when aluminum nitride is used, a film density of 3.30 g/cm³ can be obtained. In contrast, since the density of glass is 2.50 to 2.59 g/cm³, using aluminum oxide or aluminum nitride enables the formation of a dense compensation layer 114. Furthermore, densification of the compensation layer 114 suppresses outgassing from the amorphous glass substrate 102, thereby decreasing impurity incorporation into the deposited nitride semiconductor layer.

The material for forming the compensation layer 114 is not particularly limited as long as it satisfies the above-mentioned physical properties. For example, the compensation layer 114 may be formed from a single layer of aluminum nitride or aluminum oxide. The compensation layer 114 may have a structure comprising multiple stacked layers. For example, the compensation layer 114 may have a structure where, starting from the second surface F2 side of the amorphous glass substrate 102, an aluminum oxide layer and an aluminum nitride layer are stacked in that order.

As shown in Table 1, the refractive index of aluminum oxide is 1.77, while that of aluminum nitride is 2.05. In contrast, the refractive index of glass is 1.51. Therefore, when aluminum oxide or aluminum nitride is used as the compensation layer 114, the difference in refractive index allows light to be reflected at the interface with the amorphous glass substrate 102. Specifically, as shown in FIG. 1, light emitted from the light-emitting layer 1066 that has passed through the amorphous glass substrate 102 can be reflected at the interface between the amorphous glass substrate 102 and the compensation layer 114, thereby increasing the amount of light emitted from the first surface F1 side.

The thickness of the compensation layer 114 is not limited and can be set appropriately to prevent warping of the amorphous glass substrate 102. It is preferable that the compensation layer 114 is not excessively thinner than the thickness of the nitride semiconductor laminate 106. For example, the compensation layer 114 may be set to a thickness of 80% or more relative to the thickness of the nitride semiconductor laminate 106.

### (3) Buffer Layer

The buffer layer 104 is provided on the first surface F1 of the amorphous glass substrate 102. The buffer layer 104 is provided to improve the crystalline orientation of the nitride semiconductor film formed on the amorphous glass substrate 102. In other words, the buffer layer 104 is provided to crystalline grow the nitride semiconductor film in the c-axis direction.

Nitride semiconductors such as gallium nitride have a hexagonal close-packed structure and grow in the c-axis direction to minimize surface energy. As shown in Table 1, while the amorphous glass substrate 102 cannot define a lattice constant due to its amorphous nature, the lattice constant of gallium nitride is 0.3189 nm (3.189 Å), resulting in lattice mismatch between them. Therefore, even if a gallium nitride film is deposited directly onto the amorphous glass substrate 102, it will not crystallize due to the lattice mismatch and will not exhibit c-axis orientation. Therefore, a buffer layer 104 is provided on the amorphous glass substrate 102 to promote crystallization of the nitride semiconductor film. The buffer layer 104 is preferably c-axis oriented.

The buffer layer 104 is formed of a thin film having a hexagonal close-packed structure, a face-centered cubic structure, or a structure equivalent thereto. Here, a structure analogous to a hexagonal close-packed structure or a face-centered cubic structure refers to a crystal structure where the c-axis is not at 90° to the a-axis and b-axis. It is possible to promote crystal growth in the c-axis direction of the nitride semiconductor film and improve crystallinity by having the buffer layer 104 possess such a structure.

The buffer layer 104 may be, for example, aluminum nitride (AlN), aluminum oxide (AlₓO_{y}), zinc oxide (ZnO), lithium niobate (LiNbO), BiLaTiO, SrFeO, BiFeO, BaFeO, ZnFeO, PMnN-PZT, or bioapatite (BaP). The buffer layer 104 can be formed using methods such as sputtering or vapor phase growth.

The buffer layer 104 may be a single layer formed from the insulating material described above, or it may have a structure comprising multiple layers stacked together. For example, the buffer layer 104 may have a structure where, starting from the first surface F1 side of the amorphous glass substrate 102, an aluminum oxide layer and an aluminum nitride layer are stacked in that order.

Referring to Table 1, it is understood that the difference in the coefficient of thermal expansion between aluminum oxide and aluminum nitride and gallium nitride is smaller than the difference in the coefficient of thermal expansion between glass and gallium nitride. That is, by using aluminum oxide or aluminum nitride as the buffer layer 104, the difference between the thermal expansion coefficient of the buffer layer 104 and that of the gallium nitride layer as the nitride semiconductor layer can be made smaller than the difference between the thermal expansion coefficient of the amorphous glass substrate 102 and that of the gallium nitride layer as the nitride semiconductor layer. Thus, it is possible to mitigate the difference in thermal expansion coefficients by not only providing an uneven structure on the first surface F1 of the amorphous glass substrate 102, but also by providing a buffer layer 104 between the amorphous glass substrate 102 and the nitride semiconductor laminate 106.

As shown in Table 1, the refractive index of aluminum oxide is 1.77, and that of aluminum nitride is 2.05. These refractive indices lie between the refractive index of glass (1.51) and that of gallium nitride (2.4). Therefore, it is possible to suppress the reflection of light emitted from the light-emitting layer 1066 of the nitride semiconductor laminate 106 at the interface with the amorphous glass substrate 102 by using aluminum oxide or aluminum nitride as the buffer layer 104.

Furthermore, by forming the buffer layer 104 and the compensation layer 114 from homogeneous materials such as aluminum oxide and aluminum nitride, the amorphous glass substrate 102 will be sandwiched between layers formed from homogeneous materials, thereby reducing warpage.

The crystallinity of nitride semiconductor films is influenced not only by the crystallinity of the substrate but also by the microscopic surface irregularities of the substrate. Therefore, it is desirable for the buffer layer 104 to have a smooth surface with minimal irregularities. For example, it is desirable for the arithmetic mean roughness (Ra) of the surface of the buffer layer 104 to be less than 2.3 nm. Furthermore, the root mean square roughness (Rq) of the buffer layer 104 surface is preferably less than 2.9 nm. The crystallinity of the nitride semiconductor film can be enhanced when the surface roughness of the buffer layer 104 falls within this range. From the perspective of improving surface flatness, the film thickness of the buffer layer 104 is preferably 20 nm or greater.

### (4) Nitride Semiconductor Laminate

The nitride semiconductor laminate 106 includes the undoped nitride semiconductor layer 1062, the n-type nitride semiconductor layer 1064, the light-emitting layer 1066, and the p-type nitride semiconductor layer 1068. Details of each layer are shown below.

### (4-1) Undoped Nitride Semiconductor Layer

To reduce crystal dislocations in the n-type nitride semiconductor layer 1064, an undoped nitride semiconductor layer 1062 is disposed on top of the buffer layer 104. The undoped nitride semiconductor layer 1062 is formed using the same semiconductor material as the n-type nitride semiconductor layer 1064. For example, the undoped nitride semiconductor layer 1062 is formed from gallium nitride. Note that undoped means intentionally not including impurity elements for the purpose of valence electron control, and impurity elements such as oxygen, carbon, and hydrogen which are inevitably included in the undoped nitride semiconductor layer 1062 may be included. The thickness of the undoped nitride semiconductor layer 1062 is not particularly limited.

### (4-2) N-type Nitride Semiconductor Layer

The n-type nitride semiconductor layer 1064 is formed by doping the nitride semiconductor film with impurities such as silicon (Si) or germanium (Ge) to impart n-type conductivity. Specifically, the n-type nitride semiconductor layer 1064 is used as a nitride semiconductor film to which silicon (Si) or germanium (Ge) has been doped. The thickness of the n-type nitride semiconductor layer 1064 is not particularly limited but is preferably 50 nm or more and less than 3000 nm, for example. It is possible to embed the uneven structure formed on the first surface F1 of the amorphous glass substrate 102 and obtain a flat surface by forming the n-type nitride semiconductor layer 1064 with such a film thickness in addition to the doped nitride semiconductor layer 1062.

### (4-3) Light-Emitting Layer

The light-emitting layer 1066 is a region that emits light by recombining electrons transported from the n-type nitride semiconductor layer 1064 and holes transported from the p-type nitride semiconductor layer 1068. The light-emitting layer 1066 has a multi-quantum well (MQW) structure. The light-emitting layer 1066 preferably has a quantum well structure, for example, comprising alternately stacked layers of gallium nitride (GaN) and indium gallium nitride (InGaN).

### (4-4) P-type Nitride Semiconductor Layer

The p-type nitride semiconductor layer 1068 is doped with impurities such as magnesium (Mg) to impart p-type conductivity to the nitride semiconductor film. Specifically, the p-type nitride semiconductor layer 1068 is used as a p-type nitride semiconductor film doped with magnesium. Zinc (Zn) may also be used as the impurity in the p-type nitride semiconductor layer 1068. The thickness of the p-type nitride semiconductor layer 1068 is not particularly limited, but is preferably 50 nm or more and less than 500 nm, for example.

### (5) Passivation Layer

The passivation layer 108 is formed from a silicon oxide film, a silicon nitride film, or an aluminum oxide film. The passivation layer 108 may have a structure where a silicon oxide film and a silicon nitride film are stacked. The passivation layer 108 is provided to cover the nitride semiconductor laminate 106.

### (6) N-Electrode and P-Electrode

The n-electrode 110 and p-electrode 112 are provided on top of the passivation layer 108. The n-electrode 110 forms contact with the n-type nitride semiconductor layer 1064 through an opening exposing the n-type nitride semiconductor layer 1064 formed in the passivation layer 108, while the p-electrode 112 contacts the p-type nitride semiconductor layer through an opening exposing the p-type nitride semiconductor layer 1068 formed in the passivation layer 108.

The n-electrode 110 is formed from a metallic material. When the work function of the n-type nitride semiconductor layer 1064 is 3 eV to 4 eV, the n-electrode 110 is formed from a conductive material having a work function of 4.5 eV or higher, such as nickel (Ni), gold (Au), platinum (Pt), silver (Ag), and p-type silicon. The n-electrode 110 may also have a metal layer, such as aluminum (Al), laminated on top of these metal layers. The n-electrode 110 is formed, for example, to include copper (Cu) and a barrier metal layer that prevents diffusion of the copper (Cu). The barrier metal layer is formed from materials such as titanium (Ti), titanium nitride (TiN), tantalum (Ta), or tantalum nitride (TaN). The n-electrode 110 may have a structure where, for example, titanium (Ti), titanium nitride (TiN), and copper (Cu) are stacked in that order.

The p-electrode 112 is formed from metallic materials such as gold (Au), titanium (Ti)-gold (Au) alloy, or nickel (Ni), or from a transparent conductive film such as indium tin oxide (ITO). As materials for forming the p-electrode 112, metal materials with a work function smaller than 4.5 eV, such as aluminum (Al) or titanium (Ti), are selected. Although not shown, the p-electrode 112 may be formed on the upper surface of the p-type nitride semiconductor layer 1068 using a conductive metal oxide material such as indium oxide (In₂O₃), zinc oxide (ZnO), or indium tin oxide (ITO).

As described above, in the nitride semiconductor device 100A according to the present embodiment, since the uneven structure is formed on the surface of the amorphous glass substrate 102, the isotropy of thermal expansion can be relaxed, in addition, the mismatch between the thermal expansion coefficient of the amorphous glass substrate 102 and the thermal expansion coefficient of the gallium nitride semiconductor layer forming the nitride semiconductor laminate 106 can be relieved. As a result, it is possible to prevent thermal stress-induced strain from being imposed on the nitride semiconductor laminate 106 formed on the amorphous glass substrate 102, thereby improving the crystallinity of the gallium nitride-based semiconductor layer.

### Second Embodiment

Although the shape of the concave portion 1022 in FIG. 2A has a quadrilateral shape when viewed in a plan view, the uneven structure formed on the first surface F1 of the amorphous glass substrate 102 is not limited to this shape. For example, as shown in FIG. 2C, the shape of the concave portion 1022 may be circular when viewed in a plan view. Furthermore, as shown in FIG. 2D, the shape of the concave portion 1022 may be hexagonal when viewed in a plan view. Moreover, although not illustrated, the shape of the concave portion 1022 may be any polygon.

FIG. 2A, FIG. 2C, and FIG. 2D show examples where the shape of the concave portion 1022 is periodically arranged with the same shape and size, but the uneven structure formed on the first surface F1 of the amorphous glass substrate 102 is not limited to this shape. For example, as shown in FIG. 2E and FIG. 2F, the concave portions may have different sizes when viewed in a plan view, and the uneven structure may be formed with both large-pattern concave portions 1022A and small-pattern concave portions 1022B. FIG. 2E shows an example where the concave portions 1022A, 1022B are circular, and FIG. 2F shows an example where the concave portions 1022A and 1022B are hexagonal. However, this example is not limited to these shapes and the concave portions 1022A, 1022B may also be square or polygons with a greater number of sides.

Although not illustrated, the protrusions and concave portions in the uneven structure formed on the first surface F1 of the amorphous glass substrate 102 shown in FIG. 2A, FIG. 2C, FIG. 2D, FIG. 2E, and FIG. 2F may have their height relationship reversed.

The configuration of the amorphous glass substrate 102 shown in this embodiment can be applied to the nitride semiconductor device 100A shown in the first embodiment and can provide similar advantageous effects.

### Third Embodiment

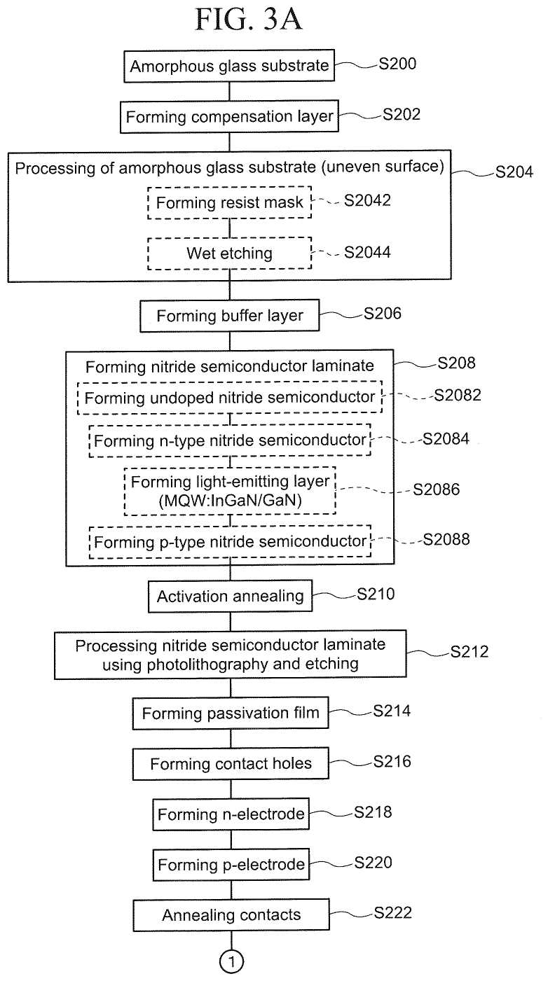

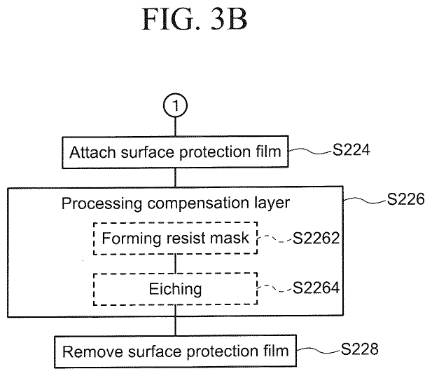

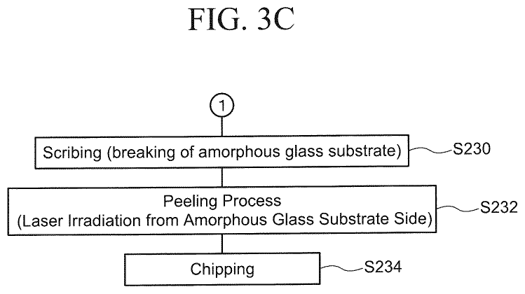

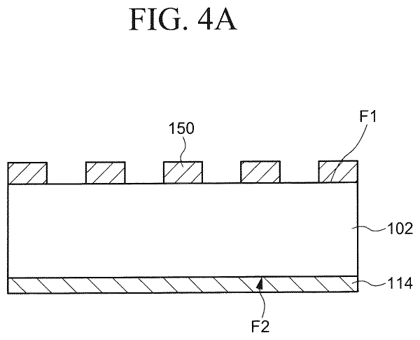

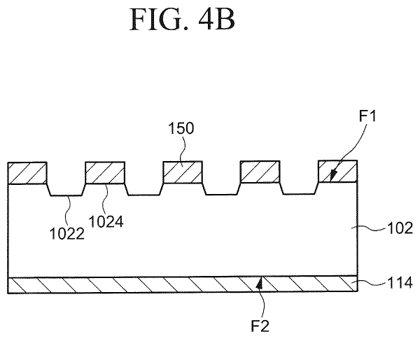

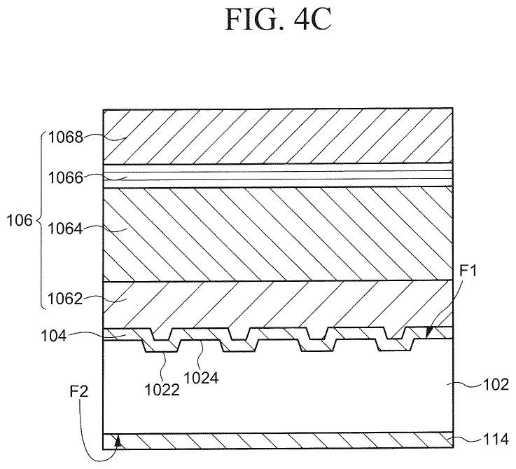

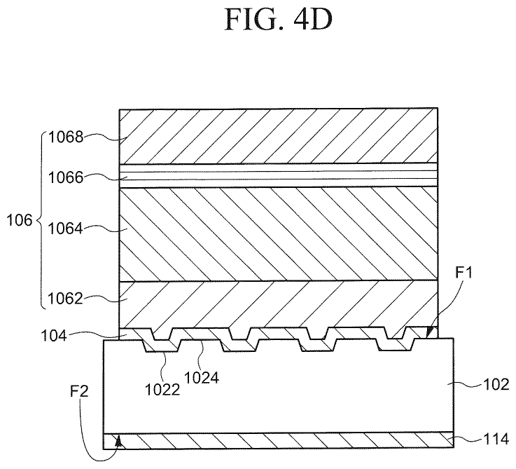

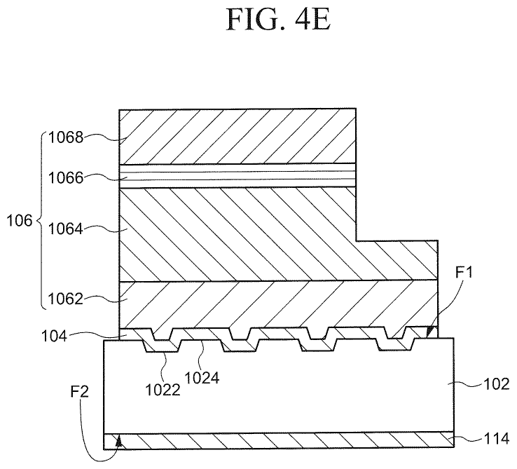

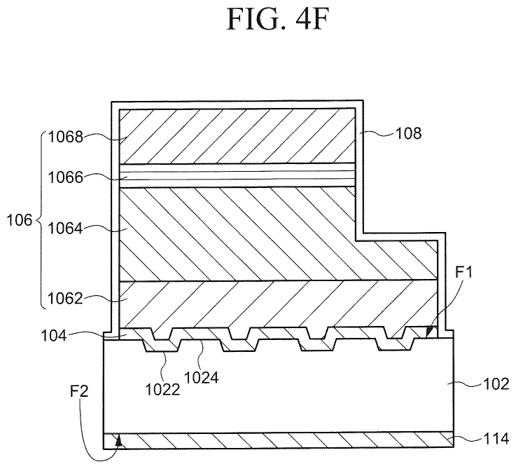

The present embodiment illustrates an example of a method for fabricating the nitride semiconductor device 100A shown in the first embodiment. FIG. 3A is a flowchart explaining the sequence of the method for fabricating the nitride semiconductor device 100A, and FIG. 4A to FIG. 4F are cross-sectional views illustrating each process step. The following description will refer to these drawings as appropriate.

First, the amorphous glass substrate 102 (FIG. 3A: S200) is prepared and the compensation layer 114 is formed on the second surface F2 (FIG. 3A: S202). Next, processing is carried out on the first surface F1 side of the amorphous glass substrate 102 (FIG. 3A: S204). The processing of the first surface F1 side of the amorphous glass substrate 102 includes the steps of forming a resist mask (FIG. 3A: S2042), etching the first surface F1 of the amorphous glass substrate 102 (FIG. 3A: S2044), and subsequently stripping the resist mask.

FIG. 4A shows a step where a compensation layer 114 is formed on the second surface F2 of the amorphous glass substrate 102, and a resist mask 150 is formed on the first surface F1. The compensation layer 114 is formed, for example, using a sputtering method. The compensation layer 114 is formed from materials such as aluminum oxide or aluminum nitride, as shown in the first embodiment. Subsequently, the resist mask 150 is formed on the first surface F1 of the amorphous glass substrate 102. The resist mask 150 is formed, for example, by coating with a photoresist and exposing it to light. The resist mask 150 has a pattern that covers the region that will be the convex portion 1024 on the first surface F1 of the amorphous glass substrate 102, exposing the region that will be the concave portion 1022.

Then, as shown in FIG. 4B, the amorphous glass substrate 102 is etched. Wet etching is used for etching the amorphous glass substrate 102. As an etching solution, for example, an etching solution primarily composed of hydrofluoric acid, ammonium fluoride, and hydrochloric acid can be used. Through this etching process, a concave portion 1022 is formed on the first surface F1 of the amorphous glass substrate 102. Since the concave portion 1022 is formed by wet etching, its side walls are not necessarily vertical and are formed with a slightly inclined shape. Although not shown in FIG. 4B, a protective film may be provided to prevent the second surface F2 of the amorphous glass substrate 102 from being eroded by the etching solution. After etching is completed, the resist mask 150 is removed.

Next, the buffer layer 104 is formed on the first surface F1 of the amorphous glass substrate 102 (FIG. 3A: S206), followed by the formation of the nitride semiconductor laminate 106 (FIG. 3A: S208). The formation of the nitride semiconductor laminate 106 is carried out in the following sequence: deposition of the undoped nitride semiconductor layer 1062 (FIG. 3A: S2082), deposition of the n-type nitride semiconductor layer 1064 (FIG. 3A: S2084), deposition of the light-emitting layer 1066 (FIG. 3A: S2086), and deposition of the p-type nitride semiconductor layer 1068 (FIG. 3A: S2088).

FIG. 4C shows the step of forming a buffer layer 104 and forming a nitride semiconductor laminate 106 on top of the buffer layer 104. The buffer layer 104 is formed from materials such as aluminum oxide or aluminum nitride, as shown in the first embodiment. For example, an aluminum nitride film is deposited as the buffer layer 104 using a sputtering method. The aluminum nitride film formed as the buffer layer 104 is deposited as a crystalline, c-axis-aligned alignment film, as described in the first embodiment.

The undoped nitride semiconductor layer 1062, the n-type nitride semiconductor layer 1064, the light-emitting layer 1066, and the p-type nitride semiconductor layer 1068 are deposited in this order on top of the buffer layer 104 using a sputtering method. For example, the undoped nitride semiconductor layer 1062, the n-type nitride semiconductor layer 1064, and the p-type nitride semiconductor layer 1068 are formed by intrinsic or respective conductivity type gallium nitride films. Furthermore, the light-emitting layer 1066 is formed to have a quantum well structure by alternately stacking gallium nitride films and indium gallium nitride films, as described in the first embodiment.

Using a multi-chamber sputtering apparatus, sputtering targets suitable for depositing the undoped nitride semiconductor layer 1062, the n-type nitride semiconductor layer 1064, the light-emitting layer 1066, and the p-type nitride semiconductor layer 1068 are installed in each chamber, therefore, this enables the sequential deposition of these layers in a vacuum environment. The nitride semiconductor laminate 106 is formed on top of the buffer layer 104, which possesses c-axis-oriented crystallinity, consequently, the crystalline alignment is controlled, resulting in high crystallinity.

After each layer of the nitride semiconductor layer is deposited, a thermal treatment is carried out for activation (FIG. 3A: S210). The thermal treatment is preferably carried out at a temperature between 600° C. and less than 800° C. in a nitrogen atmosphere. This thermal treatment activates the impurities for valence electron control in the n-type nitride semiconductor layer 1064 and the p-type nitride semiconductor layer 1068, thereby improving their conductivity.

Through the above steps, the buffer layer 104 and the nitride semiconductor laminate 106 are formed over the substantially entire first surface F1 of the amorphous glass substrate 102. Then, the nitride semiconductor laminate 106 is left in an island-like state in the region where the nitride semiconductor device is to be formed, furthermore, to enable contact formation with the n-type nitride semiconductor layer 1064, the nitride semiconductor laminate 106 is processed via photolithography and etching (FIG. 3A: S212).

FIG. 4D shows the state after the nitride semiconductor laminate 106 and buffer layer 104 have been etched. For the etching process, a predetermined resist pattern is formed on top of the nitride semiconductor laminate 106 via photolithography, after which etching is performed using a dry etching apparatus. Chlorine-based etching gases, such as Cl2, are used as the etching gas. Since the buffer layer 104 is thin, it is etched simultaneously with the nitride semiconductor laminate 106 during this etching process.

FIG. 4E shows a step in which a contact region is formed for the n-electrode 110 to form a contact with the n-type nitride semiconductor layer 1064. To form a contact between the n-electrode 110 and the n-type nitride semiconductor layer 1064, the p-type nitride semiconductor layer 1068 and the light-emitting layer 1066 are selectively etched to expose the n-type nitride semiconductor layer 1064. In this manner, the nitride semiconductor laminate 106 on the first surface F1 side of the amorphous glass substrate 102 is processed by etching, while the compensation layer 114 on the second surface F2 of the amorphous glass substrate 102 remains to prevent warping of the substrate during the process.

Next, the passivation layer 108 is formed (FIG. 3A: S214). FIG. 4F shows the stage where the passivation layer 108 is formed to cover the nitride semiconductor laminate 106. Note that the passivation layer 108 is not limited to being formed by sputtering and may also be formed, for example, by CVD.

Subsequently, contact holes are formed in the passivation layer 108 (FIG. 3A: S216), followed by the formation of the n-electrode 110 (FIG. 3A: S218) and the p-electrode 112 (FIG. 3A: S220). Furthermore, annealing is carried out so that the n-electrode 110 and p-electrode 112 form an ohmic contact with their respective nitride semiconductor layers (FIG. 3A: S222). The contact holes are formed to expose the upper surface of the n-type nitride semiconductor layer 1064 and the upper surface of the p-type nitride semiconductor layer 1068 relative to the passivation layer 108. Then, the formation of the n-electrode 110 and p-electrode 112 is carried out. As described in the first embodiment, since the preferred conductive materials for forming the n-electrode 110 and the p-electrode 112 differ, these two types of electrodes are fabricated in separate processes. There is no restriction on the order of fabrication of the n-electrode 110 and the p-electrode 112 and the p-electrode 112 may be fabricated first. Subsequently, annealing is carried out to reduce the contact resistance of the n-electrode 110 and p-electrode 112. At this step as well, the compensation layer 114 being provided over the entire second surface F2 of the amorphous glass substrate 102 prevents warping of the substrate due to the heat treatment.

The above-mentioned process results in the fabrication of the nitride semiconductor device 100A shown in FIG. 1. According to the manufacturing method for the nitride semiconductor device 100A shown in this embodiment, creating an uneven structure on the first surface F1 of the amorphous glass substrate 102 relaxes isotropic thermal expansion, due to the difference in thermal expansion coefficients, this relaxes the stress acting on the nitride semiconductor laminate 106. Furthermore, the nitride semiconductor laminate 106 undergoes compression stress in the concave portions, thereby promoting three-dimensional crystal growth. These advantageous effects prevent the layer forming the nitride semiconductor laminate 106 from delaminating from the amorphous glass substrate 102 during the manufacturing process, enabling the deposition of high-quality crystals.

### Fourth Embodiment

This embodiment differs from the first embodiment in the configuration of the compensation layer 114 and illustrates a nitride semiconductor device 100B capable of emitting light from the amorphous glass substrate 102 side. The following description explains the parts differing from the first embodiment, omitting explanations of common parts as appropriate.

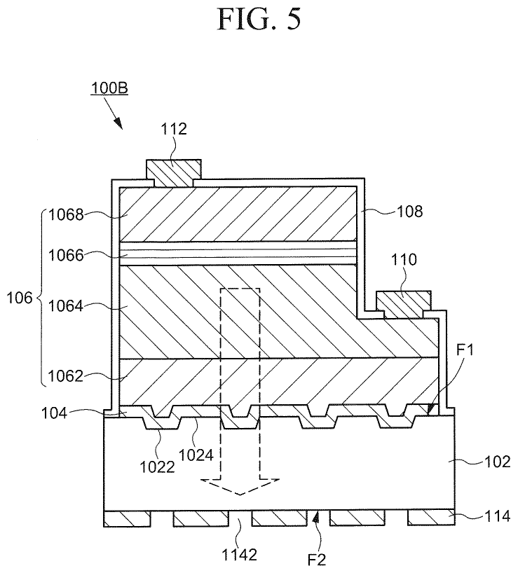

FIG. 5 shows a configuration of the nitride semiconductor device 100B according to the present embodiment. The nitride semiconductor device 100B is similar to the nitride semiconductor device 100A of the first embodiment in that a buffer layer 104, a nitride semiconductor laminate 106, a passivation layer 108, an n-electrode 110, and a p-electrode 112 are provided on the first surface F1 side of the amorphous glass substrate 102, and a compensation layer 114 is provided on the second surface F2 side. However, it is different in that the compensation layer 114 is not formed to cover the entire surface of the amorphous glass substrate 102; instead, an opening 1142 is provided to expose a portion of the second surface F2. The size and planar shape (pattern) of the opening 1142 is arbitrary and it may have a dot-like pattern, or it may have a stripe-like or grid-like pattern.

When a layer of aluminum oxide or aluminum nitride is provided as the compensation layer 114, as shown in Table 1, light emitted from the light-emitting layer 1066 is reflected due to the difference in refractive index with the amorphous glass substrate 102. In contrast, it is possible to efficiently extract light from the second surface side because an interface with air is formed in the region where the opening 1142 is provided.

FIG. 3B shows a flowchart illustrating the process of forming an opening 1142 in the compensation layer 114. The formation of the opening 1142 in the compensation layer 114 is carried out after contact annealing (FIG. 3B: S222) is completed. Since thermal processing at high temperatures is not carried out in subsequent steps, removing part of the compensation layer 114 does not cause issues such as warping of the amorphous glass substrate 102.

First, a protective film is applied to the first surface side of the amorphous glass substrate 102 to protect the nitride semiconductor laminate 106, the n-electrode 110, and the p-electrode 112. Then, the compensation layer 114 is processed (FIG. 3C: S226). For processing the compensation layer 114, a resist mask is formed in a predetermined pattern (FIG. 3C: S2262), followed by etching being carried out (FIG. 3B: S2264). The etching of the compensation layer 114 is carried out, for example, by dry etching. When an aluminum nitride film is formed as the compensation layer 114, etching can be carried out using a chlorine-based gas. After that, the resist mask is removed, and the protective film is removed (FIG. 3B: S228), thereby obtaining the nitride semiconductor device 100B having the structure shown in FIG. 5.

According to this embodiment, it is possible to provide a nitride semiconductor device 100B capable of emitting light from the amorphous glass substrate 102 side by removing a portion of the compensation layer 114. The nitride semiconductor device 100 is similar to the nitride semiconductor device 100A shown in the first embodiment, except for the different structure of the compensation layer 114, and can achieve the same functional effect.

### Fifth Embodiment

This embodiment illustrates an example of a nitride semiconductor device 100C having a structure where the nitride semiconductor laminate 106 is separated from the amorphous glass substrate 102. The following description explains the parts differing from the first embodiment, omitting explanations of common parts as appropriate.

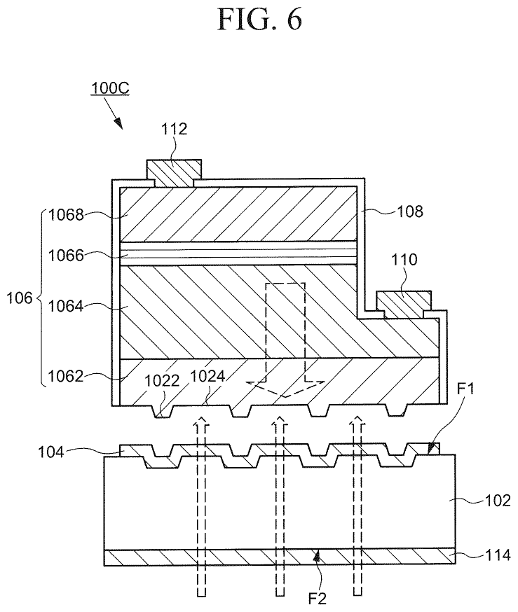

FIG. 6 shows the configuration of the nitride semiconductor device 100C according to the present embodiment. As shown in FIG. 6, the nitride semiconductor device 100C has a structure in which the layer above the nitride semiconductor laminate 106 is peeled off and thinned at the interface between the buffer layer 104 and the undoped nitride semiconductor layer 1062. Separation between the amorphous glass substrate 102 side and the nitride semiconductor laminate 106 side can be carried out by irradiating with laser light.

FIG. 3C shows a flowchart illustrating the process of separating the upper layer from the nitride semiconductor laminate 106 from the amorphous glass substrate 102. When manufacturing the nitride semiconductor device shown in the third embodiment using a large-area amorphous glass substrate, referred to as a mother glass, a scribing process is carried out to divide the large-area amorphous glass substrate into multiple pieces before the laser light irradiation peeling process (FIG. 3C: S230). The scribing process is carried out using either a laser scribing method or a mechanical scribing method. The laser scribing method involves focusing and irradiating laser light to locally heat and melt the amorphous glass substrate for processing, and the mechanical scribing method involves cutting a scoring line into the glass using a scribing blade (for example, a scribing wheel) to fracture the amorphous glass substrate.

Thereafter, the nitride semiconductor laminate 106 is peeled by irradiating a laser beam from the side of the amorphous glass substrate 102 (FIG. 3C: S232). For the laser light, wavelengths that transmit through the amorphous glass substrate 102 and are absorbed by the nitride semiconductor are applied. For example, since the bandgap of gallium nitride is 3.4 eV, using the third harmonic (355 nm, 3.49 eV) of a YAG laser allows the laser light to pass through the amorphous glass substrate 102, the buffer layer 104, and the compensation layer 114 formed of aluminum oxide and aluminum nitride without being absorbed, and the undoped nitride semiconductor layer 1062 can be locally heated at the interface between the nitride semiconductor laminate 106 and the buffer layer 104 to carry out delamination.

When carrying out the peeling process, a protective film may be attached to the first surface F1 of the amorphous glass substrate 102 to protect the nitride semiconductor device 100C after peeling. Since the peeled nitride semiconductor device 100C has a thickness of about 10 μm, it is mounted on a predetermined die and processed into a chip (FIG. 3C: S234). The peeled nitride semiconductor device 100C can also be mounted on an array substrate (also referred to as a “backplane”) on which pixel circuits are formed with thin film transistors.

According to the present embodiment, it is possible to reduce the thickness of the nitride semiconductor device 100C by peeling the layer above the nitride semiconductor laminate 106 from the amorphous glass substrate 102. Since the nitride semiconductor device 100C has a structure peeled at the interface between the buffer layer 104 and the nitride semiconductor laminate 106, and the peeled surface is formed with a rugged surface following the rugged structure of the amorphous glass substrate 102, the light extraction efficiency can be enhanced by using this surface as a light emitting surface.

As described above, the respective configurations of the nitride semiconductor devices shown in the first through fifth embodiments may be appropriately combined and implemented, provided they do not conflict with each other. Based on each embodiment, variations where a person skilled in the art appropriately adds, deletes, or redesigns components, or adds, omits, or changes process conditions, are also included within the scope of the present invention, provided they embody the essence of the invention.

It is understood that other advantageous effects, even if different from those provided by the above-described embodiments, which are apparent from the description herein or readily foreseeable by those skilled in the art, are naturally provided by the present invention.

What is claimed is:

1. A nitride semiconductor device comprising:
an amorphous glass substrate having a first surface and a second surface opposite the first surface;
a buffer layer provided on the first surface of the amorphous glass substrate; and
a nitride semiconductor laminate including at least one gallium nitride layer disposed on the buffer layer,
wherein the first surface of the amorphous glass substrate has an uneven structure comprising a convex surface having a flat top portion and a concave surface having a flat bottom portion, and
wherein the buffer layer and the nitride semiconductor laminate are disposed on the uneven structure.

2. The nitride semiconductor device according to claim 1, wherein the uneven structure has a length of the convex surface having the flat top portion and the concave surface having the flat bottom portion in a range of 5 μm to 80 μm, and a height difference between the flat convex surface and the flat concave surface in a range of 0.3 μm to 3 μm.

3. The nitride semiconductor device according to claim 1, wherein a thermal expansion coefficient of the buffer layer is between a thermal expansion coefficient of the amorphous glass substrate and a thermal expansion coefficient of the at least one gallium nitride layer, and
a difference between the thermal expansion coefficient of the buffer layer and the thermal expansion coefficient of the at least one gallium nitride layer is smaller than a difference between the thermal expansion coefficient of the amorphous glass substrate and the thermal expansion coefficient of the at least one gallium nitride layer.

4. The nitride semiconductor device according to claim 3, wherein a refractive index of the buffer layer is between a refractive index of the amorphous glass substrate and a refractive index of the at least one gallium nitride layer.

5. The nitride semiconductor device according to claim 1, further comprising a compensation layer on the second surface of the amorphous glass substrate,
wherein a refractive index of the compensation layer is between a refractive index of the amorphous glass substrate and a refractive index of the at least one gallium nitride layer.

6. The nitride semiconductor device according to claim 1, wherein the buffer layer comprises at least one of an aluminum nitride layer and an aluminum oxide layer.

7. The nitride semiconductor device according to claim 5, wherein the compensation layer comprises at least one selected from an aluminum nitride layer and an aluminum oxide layer.

8. The nitride semiconductor device according to claim 1, wherein the buffer layer includes an aluminum oxide layer and an aluminum nitride layer laminated in this order from the first surface side.

9. The nitride semiconductor device according to claim 5, wherein the compensation layer includes an aluminum oxide layer and an aluminum nitride layer laminated in this order from the second surface side.

10. The nitride semiconductor device according to claim 1, wherein the nitride semiconductor laminate includes, laminated in order from the buffer layer side, an n-type nitride semiconductor layer, a light-emitting layer, and a p-type nitride semiconductor layer, and
the at least one gallium nitride layer comprises the n-type nitride semiconductor layer and the p-type nitride semiconductor layer.

11. The nitride semiconductor device according to claim 10, wherein the nitride semiconductor laminate is separated from an interface with the buffer layer, and a separated surface is used as a light-emitting surface.

12. A method for manufacturing a nitride semiconductor device comprising:
forming an uneven structure on a first surface of an amorphous glass substrate having the first surface and a second surface opposite the first surface, the uneven structure including a convex surface having a flat top portion and a flat concave surface having a flat bottom portion;
forming a buffer layer on the uneven structure; and
forming a nitride semiconductor laminate including at least one gallium nitride layer on the buffer layer,
wherein the uneven structure is formed by etching the amorphous glass substrate.

13. The method according to claim 12, further comprising:
forming a compensation layer on the second surface of the amorphous glass substrate.

14. The method according to claim 12, wherein the uneven structure is formed with a length of the flat surface of the convex surface having the flat top portion and the concave surface having the flat bottom portion being 5 μm to 80 μm, and the height difference between the convex surface having the flat top portion and the concave surface having the flat bottom portion is formed to be 0.3 μm to 3 μm.

15. The method according to claim 12, wherein the buffer layer is formed of at least one layer selected from an aluminum nitride layer and an aluminum oxide layer.

16. The method according to claim 12, wherein the compensation layer is formed of at least one layer selected from an aluminum nitride layer and an aluminum oxide layer.

17. The method according to claim 12, wherein the buffer layer is formed by laminating an aluminum oxide layer and an aluminum nitride layer in this order from the first surface side.

18. The method according to claim 13, wherein the compensation layer is formed by laminating an aluminum oxide layer and an aluminum nitride layer in this order from the second surface side.

19. The method according to claim 12, wherein laser light is irradiated from a side of the amorphous glass substrate to separate the nitride semiconductor laminate at an interface with the buffer layer.
